(19) United States
(12) Patent Application Publication
(10) Pub. No.: US 2008/0119059 A1
(43) Pub. Date: May 22, 2008

(54) LOW THERMAL BUDGET CHEMICAL VAPOR DEPOSITION PROCESSING

(76) Inventors: Jacob W. Smith, Santa Clara, CA (US); R. Suryanarayanan Iyer, Edina, MN (US); Yuji Maeda, Chiba (JP)

Correspondence Address: Karen M. Whitney;APPLIED MATERIALS, INC., Legal Affairs Department, P.O.Box 450-A, Santa Clara, CA, 95035, US

(21) Appl. No.: 11/561,858

(22) Filed: Nov. 20, 2006

(51) Int. Cl. H01L 21/31

(52) U.S. Cl. 438/787

(57) ABSTRACT

Methods for low thermal budget silicon dioxide chemical vapor deposition in single-wafer chambers are provided. In semiconductor manufacturing, Si₂H₆-based oxide deposition is worthy of consideration as a viable alternative to higher temperature thermal CVD processes. A process of forming a film on a substrate is provided, the process comprising: placing a substrate in a thermal low-pressure chemical vapor deposition single-wafer chamber; flowing disilane (Si₂H₆) into the chamber; flowing nitrous oxide (N₂O) into the chamber at a ratio of at least approximately 300:1 N₂O:Si₂H₆; heating the chamber at a temperature of from approximately 450° C. to approximately 550° C.; and forming the film on the substrate, wherein the film comprises silicon dioxide (SiO₂).

### FIELD

Methods of low thermal budget chemical vapor deposition (CVD) processing are provided. In one aspect, silicon oxide films using disilane as a precursor is provided.

### BACKGROUND

Chemical vapor deposited (CVD) SiO₂ films and their binary and ternary silicates (generally referred to as oxide films) have wide use in fabrication of integrated circuits such as microprocessors and memories. These films are used as insulation between polysilicon and metal layers, between metal layers in multilevel metal systems, as diffusion sources, as diffusion and implantation masks, as spacers, and as final passivation layers. Acceptable deposited oxide film processes provide uniform thickness and composition, low particulate and chemical contamination, good adhesion to the substrate, and high throughput for manufacturing.

These films are formed using well known techniques such as CVD. Low-pressure chemical vapor deposition (LPCVD) is a special case of a CVD process, typically used for front end of line (FEOL) dielectric film deposition. In a CVD process, a given composition and flow rate of reactant gases and diluent carrier gases are introduced into a reaction chamber. The gas species move to a substrate and the reactants are adsorbed on the substrate. The atoms undergo migration and film-forming chemical reactions and a film (e.g., silicon oxide) is deposited on the substrate. The gaseous byproducts of the reaction and removed from the reaction chamber. Energy to drive the reactions can be supplied by several methods, e.g. thermal, light and radio frequency, catalysis, or plasma. Low pressure CVD methods are described in U.S. Pat. No. 6,713,127 to Applied Materials, Inc., which is incorporated herein in its entirety.

Reducing thermal budgets of these processes reduces expenses of operating CVD apparatus. Moreover, the industry continues to progress towards smaller, more compact, faster, and more powerful chips, thereby downscaling device geometries. The move to smaller device geometries to, for example, 65 nm technology and beyond, drives a need for low thermal budget thin film dielectric processes. A variety of fabrication methods have been developed for low thermal budget processing, including plasma-enhanced CVD (PECVD), electron cyclotron CVD (ECRCVD), photo-CVD, and laser-induced CVD. Common problems for these methods include poor step coverage, substrate damage, and poor film uniformity. Film growth without substrate heating is achievable but yields poor film quality. A common method is PECVD, which typically operates at 120-350° C.

Thermal chemical vapor deposition (CVD) has utilized silane (SiH₄) or dichlorosilane (SiCl₂H₂) in conjunction with N₂O, but both single-wafer and batch processing typically require temperatures of 700-850° C. to achieve reasonable deposition rates on the wafer surface. Certain batch processes can operate below 600° C. but require longer processing time, resulting in a higher thermal budget.

There is a need, therefore, to provide apparatus and methods for chemical vapor deposition with low thermal budgets and excellent film quality.

### SUMMARY

Methods for low thermal budget silicon dioxide chemical vapor deposition in single-wafer chambers are provided. In semiconductor manufacturing, Si₂H₆-based oxide deposition is worthy of consideration as a viable alternative to higher temperature thermal CVD processes. In one aspect, a process of forming a film on a substrate is provided, the process comprising: placing a substrate in a thermal low-pressure chemical vapor deposition single-wafer chamber; flowing disilane (Si₂H₆) into the chamber; flowing nitrous oxide (N₂O) into the chamber at a ratio of at least approximately 300:1 N₂O:Si₂H₆; heating the chamber at a temperature of from approximately 450° C. to approximately 550° C.; and forming the film on the substrate, wherein the film comprises silicon dioxide (SiO₂).

In one embodiment, a pressure of the chamber is from approximately 150 Torr to approximately 325 Torr. In a specific embodiment, the chamber is at a pressure of approximately 275 Torr. In another embodiment, the disilane flows a flow rate of from approximately 5 to approximately 30 sccm. The nitrous oxide flows at a flow rate of from approximately 3 to approximately 10 slm in yet another embodiment.

The process can further comprise flowing a carrier gas into the chamber at a flow rate of approximately 1 to approximately 7 slm. In one embodiment, the carrier gas comprises nitrogen (N₂). In another embodiment, the carrier gas comprises another inert gas such as H2, He, and Ar. In a further embodiment, the nitrogen flows at a ratio from approximately 33:1 to 1400:1 N₂:Si₂H₆. The ratio is from approximately 50:1 to 300:1 N₂:Si₂H₆ in another embodiment.

In certain embodiments, the film is formed at a deposition rate of at least 35 Å/min. In some embodiments, the film has a refractive index of approximately 1.45.

### BRIEF DESCRIPTION OF THE FIGURES

The teachings of the present invention can be readily understood by considering the following detailed description in conjunction with the accompanying drawings, in which:

FIG. 1 is a side-view, cross-sectional schematic of an exemplary low pressure chemical vapor processing chamber that can perform methods of the present invention;

FIG. 2 is a graph showing refractive index trend profiles with respect to temperature, pressure, and process gas; and

FIG. 3 flows is a graph comparing deposition rate and RI of disilane processes compared to a silane process.

### DETAILED DESCRIPTION

Disilane-based low thermal budget silicon dioxide chemical vapor deposition processes in single-wafer chambers provide viable alternatives to silane-based, high temperature commercial processes.

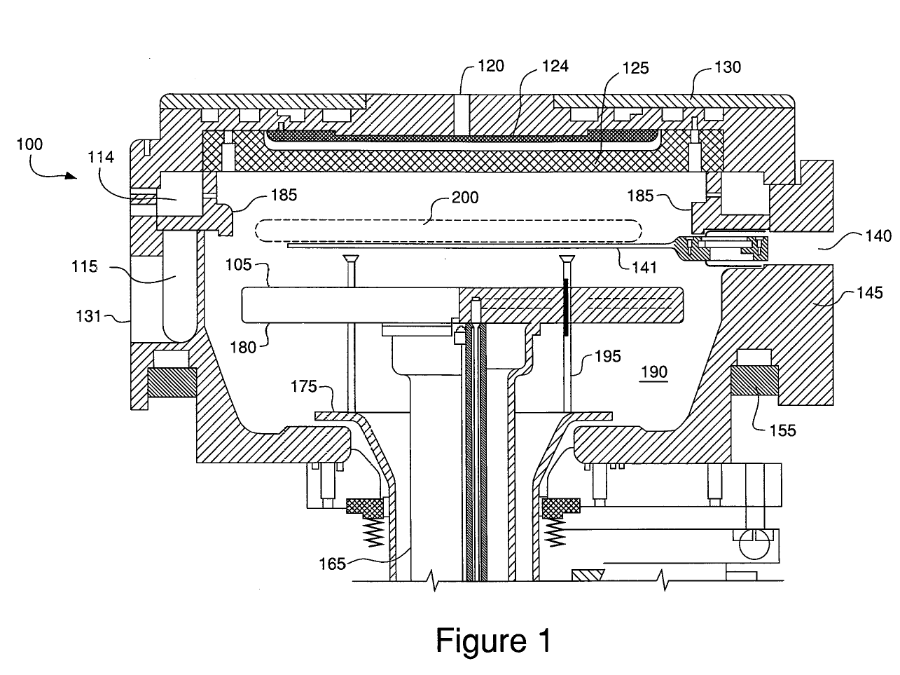

An exemplary thermal low-pressure chemical vapor deposition chamber that can be used to practice the present invention is provided in FIG. 1. This figure depicts a cross-sectional side-view of a chamber in a “wafer-load” position. In one embodiment, the chamber is approximately 5 to 6 liters.

FIG. 1 illustrates a chamber body 145 that defines reaction chamber 190 in which process gases or reactant gases are thermally decomposed to form a silicon oxide film on substrate 200. The chamber body 145 is constructed, in one embodiment, of aluminum and has passages 155 for water (or a mixture of water and ethylene glycol) to be pumped therethrough to cool chamber body 145. The water passages enable the apparatus 400 to be a “cold-wall” reactor chamber. Chamber body 145 is also constructed of materials that enable pressure in the chamber to be maintained between 0 to 350 Torr.

The chamber body 145 houses the chamber 190, a chamber lid 130, distribution port 120, face plate (or shower head) 125, blocker plate 124, heater pocket 105, and resistive heater 180. The heater pocket 105 is positioned on resistive heater 180 and is further supported by shaft 165. The heater pocket 105 has a surface area sufficient to support the substrate 200 such as a semiconductor wafer (shown in dashed lines). In one example, the heater pocket 105 is a substrate holder for substrate 200. The heater pocket 105 also heats up the substrate 200 during deposition. The chamber body 145 also houses lift pins 195 and a lift plate 175 which are operatively connected to a lifter assembly (not shown). The lift plate 175 is positioned at the base of chamber 190. Lift pins 195 extend and retract through a plurality of through openings, through bores, or holes in the surface of the heater pocket 105 to lift the substrate 200 off heater pocket 105. As lift pins 195 retract, the substrate 200 can be removed from the chamber body 145. The chamber body 145 can also receive a transfer blade 141 which is a robotic mechanism used to insert the substrate 200 through an opening 140.

As the substrate 200 is being loaded, heater 180 is lowered so that the surface of the heater pocket 105 is below the opening 140 so that substrate 200 can be placed into chamber 190. Once loaded, the opening 140 is sealed and heater 180 is advanced in a superior (e.g., upward) direction toward face plate 125 by the lifter assembly (not shown) that is, for example, a stepper motor. The advancement stops when the substrate 200 is a short distance (e.g., 400-700 mm) from faceplate 125. When the substrate 200 is properly positioned in chamber 190, the heater pocket 105 and the heater 180 heat the substrate 200 to a desired processing temperature for the deposition process. The temperature for film deposition inside chamber 190 is controlled by a resistive heater 180.

The substrate 200 can be removed from chamber 190 (for example, upon the completion of the deposition) first by being separated from the surface of heater pocket 105. The transfer blade 141 of a robotic mechanism is inserted through the opening 140 beneath the heads of lift pins 195 which support the substrate 200. Next, the lifter assembly (not shown) moves (e.g., lowers) heater 180 and lifts plate 175 to a “wafer load” position, as depicted in FIG. 1. By moving lift plates 175 in an inferior direction, lift pins 195 are also moved in an inferior direction, until the surface of the processed wafer contacts the transfer blade. The processed substrate 200 is then removed through the opening 140 by, for example, a robotic transfer mechanism that removes the substrate 200 and transfers the substrate to the next processing (e.g., cooling) step.

The mechanism described above may be repeated for subsequent substrates 200. A detailed description of one suitable lifter assembly is described in U.S. Pat. No. 5,772,773, assigned to Applied Materials, Inc. of Santa Clara, Calif.

The thermal LPCVD apparatus 100 also includes a temperature indicator (not shown) to monitor the processing temperature inside the chamber 190. The temperature indicator can be positioned such that it conveniently provides data about the temperature at the surface of heater pocket 105 (or at the surface of a wafer on heater pocket 105).

Chamber body 145 further couples to a gas delivery system which delivers reactant gases, stabilization gases or cleaning gases to chamber 190. Cleaning gases (e.g., argon, nitrogen trifluoride, and N₂) can be injected into the chamber 190 after the deposition process. For instance, after a deposition process or between runs, chamber 190 is purged with the cleaning gases that are released from a manifold.

The chamber body 145 also couples to a pressure regulator or regulators (not shown). The pressure regulators establish and maintain pressure in chamber 190. In one embodiment, for example, such pressure regulators are known in the field as baratron pressure regulator(s).

The chamber body 145 also couples to a gas out system through which gases are pumped out of the chamber. The gas outlet system includes a pumping plate 185 which pumps residual process gases from the chamber 190 to a collection vessel at a side of the chamber body 145 (e.g., vacuum pump-out 131). The pumping plate 185 creates two flow regions resulting in a gas flow pattern that creates a uniform silicon layer on a substrate. In one example, the vacuum pump-out 131 couples to a pump disposed exterior to the chamber 190. In this example, pump-out 131 provides vacuum pressure within pumping channel 115 (below channel 114) to draw both the reactant and purge gases out of chamber 190 through vacuum pump-out 131. The pump can also divert the silicon source gas away from chamber 190 when necessary.

### EXAMPLES

Thermal deposition experiments were performed in a 300 mm single-wafer CVD chamber under subatmosphere conditions. The wafer was supported on a resistively heated ceramic susceptor. Discussion of temperature is that of the process chamber heater setting, unless otherwise noted. Generally, wafer temperature is approximately 25° C. cooler than the heater setting. A continuous flow process was used, whereby process gases were distributed from above the substrate via a showerhead assembly and exited the chamber at an exhaust port. Temperature and pressure were controlled by an in situ thermocouple and manometer, respectively. N₂O and Si₂H₆ were used as oxygen and silicon source precursors, respectively. Typical total gas flow rates were 6-13 standard liters per minute (slm) with nitrogen utilized as a carrier gas for Si₂H₆. SiO₂ films of 100-500 Å thickness were deposited on a silicon substrate, targeting 250 Å. The process domain utilized for the experiments is shown in Table 1. Refractive Index (RI) and film thickness were measured by spectroscopic ellipsometry. Chemical composition of the deposited films was determined using Rutherford backscattering and hydrogen forward scattering spectroscopy (HFS/RBS). Wafers wore dipped in a 200:1 dilute (in water) HF solution to obtain wet etch rate data.

TABLE 1
Process domain for thermal CVD of SiO₂

| Parameter | Range |
|---|---|
| Temperature, ° C. | 450–550 |
| Pressure, Torr | 150–325 |
| Si₂H₆ flow | 5–30 |
| sccm | |
| N₂O flow | 3–10 |
| slm | |
| N₂ flow | 1–7 |
| slm | |

### Results and Discussion

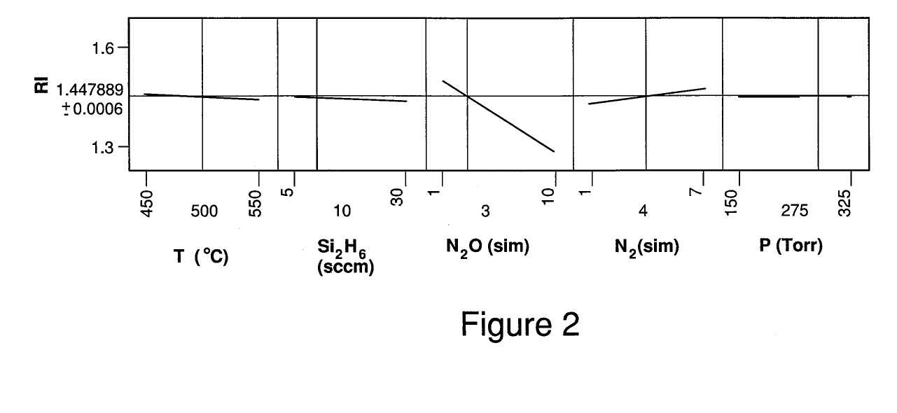

A statistical fit of RI was employed to identify relative sensitivity to the independent parameters. The trend plots are shown in FIG. 2. N₂O flow appears to be the dominant factor determining RI.

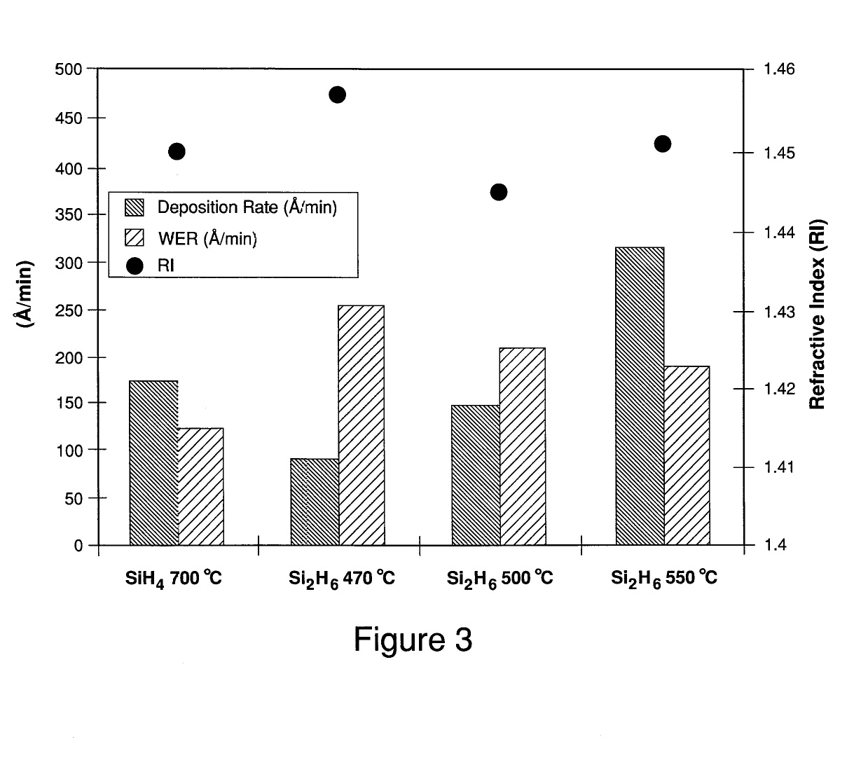

A 700° C. SiH₄—N₂O process used in the semiconductor industry was utilized as a benchmark for comparison to Si₂H₆. FIG. 3 shows that deposition rate and RI for a 500° C. Si₂H₆ process are 147 Å/min and 1.445, respectively, and are similar to the 700° C. SiH₄ process (174 Å/min, RI=1.450). At 550° C. the deposition rate is 315 Å/min, exceeding the benchmark SiH₄ process. In addition, at 470° C. a deposition rate of 90 Å/min was obtained, demonstrating that oxide deposition using thermal CVD is achievable below 500° C.

The composition of the films obtained by HFS/RBS is shown in Table 2. For comparison, data for the benchmark 700° C. SiH₄—N₂O process is also included. The Si₂H₆ process has higher hydrogen content; however, both processes deposit nearly stoichiometric films that are slightly Si-rich compared with stoichiometric (O/Si=2) silicon dioxide. The wet etch rate (WER), also shown in FIG. 3, is greater for all Si₂H₆ films compared to the SiH₄ baseline. Although low etch rates are desirable for better control when etching the film, films with high WER may be compensated for by tuning the etch process.

TABLE 2
Composition of SiO₂ Films

| Process | Si (atom %) | O (atom %) | O/Si ratio | H (atom %) |
|---|---|---|---|---|
| 500° C. disilane | 550–500 | 0.97 | 0.11 | 0.85 |
| 700° C. silane | 500–450 | 0.74 | 0.08 | 1.92 |

Additionally, FIG. 3 shows that WER for Si₂H₆ films increases with decreasing temperature. The WER is indirectly a measure of film density, as it takes less time to etch a film with a higher void fraction. The data indicate the Si₂H₆ films are generally less dense than the 700° C. SiH₄ process and that the film density decreases inversely with temperature. Based on RI and HFS/RBS data, the disilane process is stoichiometrically equivalent to the benchmark silane process, except for a higher H content in the lower temperature disilane-based film.

Table 3 provides the operating data and results at conditions of 450° C. with parameters of pressure, dilisane flow, nitrous oxide flow, nitrogen flow varied.

TABLE 3

| | | | | Deposition | |
|---|---|---|---|---|---|
| Pressure | Si₂H₆ | N₂O | N₂ | Rate | |
| (Torr) | (sccm) | (slm) | (slm) | (Å/min) | RI |
| 275 | 10 | 5 | 3 | 14 | 1.4532 |
| 325 | 10 | 5 | 3 | 26 | 1.4561 |
| 275 | 10 | 5 | 1 | 36 | 1.4552 |
| 275 | 20 | 5 | 1 | 23 | 1.4933 |
| 275 | 20 | 10 | 1 | 38 | 1.456 |

Although the invention herein has been described with reference to particular embodiments, it is to be understood that these embodiments are merely illustrative of the principles and applications of the present invention. It will be apparent to those skilled in the art that various modifications and variations can be made to the methods of the present invention without departing from the spirit and scope of the invention. Thus, it is intended that the present invention include modifications and variations that are within the scope of the appended claims and their equivalents.

What is claimed is:

1. A process of forming a film on a substrate, the process comprising:
placing a substrate in a thermal low-pressure chemical vapor deposition single-wafer chamber;
flowing disilane (Si₂H₆) into the chamber;
flowing nitrous oxide (N₂O) into the chamber at a ratio of at least approximately 300:1 N₂O:Si₂H₆;
heating the chamber at a temperature of from approximately 450° C. to approximately 550° C.; and
forming the film on the substrate, wherein the film comprises silicon dioxide (SiO₂).

2. The process of claim 1, wherein a pressure of the chamber is from approximately 150 Torr to approximately 325 Torr.

3. The process of claim 2, wherein the pressure is approximately 275 Torr.

4. The process of claim 1, wherein the disilane flows a flow rate of from approximately 5 to approximately 30 sccm.

5. The process of claim 1, wherein the nitrous oxide flows at a flow rate of from approximately 3 to approximately 10 slm.

6. The process of claim 1, further comprising flowing a carrier gas into the chamber at a flow rate of approximately 1 to approximately 7 slm.

7. The process of claim 6, wherein the carrier gas comprises nitrogen (N₂).

8. The process of claim 7, wherein the nitrogen flows at a ratio of from approximately 33:1 to 1400:1 N₂:Si₂H₆.

9. The process of claim 1, wherein the film is formed at a deposition rate of at least 35 Å/min.

10. The process of claim 1, wherein the film has a refractive index of approximately 1.45.
